(19) United States
(12) Patent Application Publication
(10) Pub. No.: US 2018/0373666 A1
(43) Pub. Date: Dec. 27, 2018

(54) CURRENT/VOLTAGE MEASURING SYSTEM AND METHOD

(71) Applicant: Primax Electronics Ltd., Taipei (TW)

(72) Inventors: Ying-Che TSENG, Taipei (TW); Cheng-Yi TSAI, Taipei (TW)

(21) Appl. No.: 15/835,899

(22) Filed: Dec. 8, 2017

(30) Foreign Application Priority Data
Jun. 23, 2017 (TW) 106121100

(51) Int. Cl. G06F 13/42; G01R 19/165

(52) U.S. Cl. CPC G06F 13/426; G06F 2213/0042; G01R 19/165

(57) ABSTRACT

A current/voltage measuring system for measuring a current value and a voltage value of an electronic device includes a microcontroller, a connection interface, an interface detecting chip, a current/voltage measuring chip, a hub control chip, a microcontroller and a transmission module. When the electronic device is connected with a connection interface, the microcontroller detects an interface type of the electronic device through the interface detecting chip. Then, the microcontroller controls the hub control chip to output a rated current to the connection interface according to the interface type. Then, the current/voltage measuring chip reads the current value and the voltage value and transmits the current value and the voltage value to the microcontroller. Then, the microcontroller generates a test record according to the current value and the voltage value, and the microcontroller transmits the test record to a control platform through the transmission module.

### FIELD OF THE INVENTION

The present invention relates to a measuring system, and more particularly to a measuring system for measuring a current value and a voltage value of an electronic device through a transmission interface.

### BACKGROUND OF THE INVENTION

With the development of today's technology, various electronic devices such as desktop computers, notebook computers, tablet computers, personal digital assistants (PDA), smart phones, external hard drives, flash drives, printers, office machines, mouse devices, keyboard devices or video cameras have gradually become indispensable auxiliary tools in people's lives or work.

While various electronic devices are used, a great number of data files are generated. Moreover, different transmission interfaces are employed for transmitting data files or transmitting electric power between different electronic devices. However, when different electronic devices are in communication with each other, the connected electronic devices are possibly damaged because a problem of overloading electric power is generated. For solving this problem, it is important to detect the current values and the voltage values of the electronic devices during the process of fabricating the electronic devices.

For example, U.S. Pat. No. 6,629,169 B2 discloses an apparatus and a method for testing a universal serial bus (USB) device. A microcontroller (MCU) of the apparatus can actively test the USB device that is connected with a host terminal Moreover, Taiwanese Patent No. TWI550296 discloses an apparatus and a method for detecting the type of a USB cable. The type of the USB cable is judged according to the detecting result.

However, the conventional technologies still has some drawbacks. For example, when the electronic device with plural transmission interfaces are tested, the operator or the line administrator on the production line cannot realize the detecting results of each electronic device in real time.

Therefore, there is a need of providing a measuring system for testing an electronic device with different transmission interfaces and allowing the operator or the line administrator on the production line to realize the detecting results of each electronic device in real time.

### SUMMARY OF THE INVENTION

An object of the present invention provides a current/voltage measuring device for realizing and monitoring a test record of an electronic device on a production line in real time.

In accordance with an aspect of the present invention, there is provided a current/voltage measuring system for measuring a current value and a voltage value of an electronic device. The current/voltage measuring system includes a connection interface, an interface detecting chip, a current protection module, a current/voltage measuring chip, a hub control chip, a microcontroller and a transmission module. The interface detecting chip is electrically connected with the connection interface. The current protection module is electrically connected with the interface detecting chip. The current protection module judges whether the connection interface is in an overloading condition. The current/voltage measuring chip is electrically connected with the current protection module. The hub control chip is electrically connected with the current/voltage measuring chip. The microcontroller is electrically connected with the interface detecting chip, the current/voltage measuring chip and the hub control chip. The transmission module is electrically connected with the microcontroller. After the electronic device is connected with the connection interface, the microcontroller detects an interface type of the electronic device through the interface detecting chip. Then, the microcontroller controls the hub control chip to output a rated current to the connection interface according to the interface type. Then, the current/voltage measuring chip reads the current value and the voltage value and transmits the current value and the voltage value to the microcontroller. Then, the microcontroller generates a test record according to the current value and the voltage value, and the microcontroller transmits the test record to a control platform through the transmission module.

In an embodiment, the connection interface comprises a USB interface or a lightning interface.

In an embodiment, the USB interface is a USB 2.0 interface, a USB 3.0 interface or a USB 3.1 interface.

In an embodiment, the current protection module comprises at least one current protection chip and at least one switch chip.

In an embodiment, the at least one current protection chip detects whether the connection interface is in the overloading condition. If the connection interface is in the overloading condition, a power supply circuit is interrupted by the switch chip.

In an embodiment, the hub control chip is electrically connected with an external power source, and the external power source provides electric energy for powering the current/voltage measuring system.

In an embodiment, the transmission module is a wired transmission module or a wireless transmission module.

In an embodiment, the wired transmission module is an Ethernet transmission module, a token-ring transmission module or a fiber-optic communication module.

In an embodiment, the wireless transmission module includes is an infrared transmission module, a Bluetooth transmission module, a ZigBee wireless network module or a Wi-Fi transmission module.

In an embodiment, the control platform is a calculator, a cloud server or a mobile device.

In an embodiment, the mobile device is a notebook computer, a tablet computer, a personal digital assistant or a smart phone.

In an embodiment, the current/voltage measuring system further includes a warning module. A warning message or a test completion message is shown on or emitted by the warning module.

In accordance with another aspect of the present invention, there is provided a current/voltage measuring method for measuring a current value and a voltage value of an electronic device. The current/voltage measuring method includes the following steps. In a step (a), the electronic device is provided. In a step (b), an interface type of the electronic device is detected when the electronic device is connected with a connection interface. In a step (c), a rated current is provided according to the interface type. Then, a step (d) is performed to judge whether the connection interface is in an overloading condition. If the connection interface is in the overloading condition, a power supply circuit for powering the connection interface is interrupted. If the connection interface is not in the overloading condition, a next step is performed. In a step (e), the current value and the voltage value of the electronic device are read. Then, a step (f) is performed to judge whether the current value and the voltage value of the electronic device comply with production specifications. In a step (g), a test record is generated. In a step (h), the test record is transmitted to a control platform.

In an embodiment, the step (h) further includes a step of generating a test completion message to the control platform after the test record is completely transmitted to the control platform.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic functional block diagram illustrating a current/voltage measuring system according to an embodiment of the present invention;

FIG. 2 is a flowchart illustrating a current/voltage measuring method according to an embodiment of the present invention; and

FIG. 3 is a flowchart illustrating the step S109 of the current/voltage measuring method of FIG. 2.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

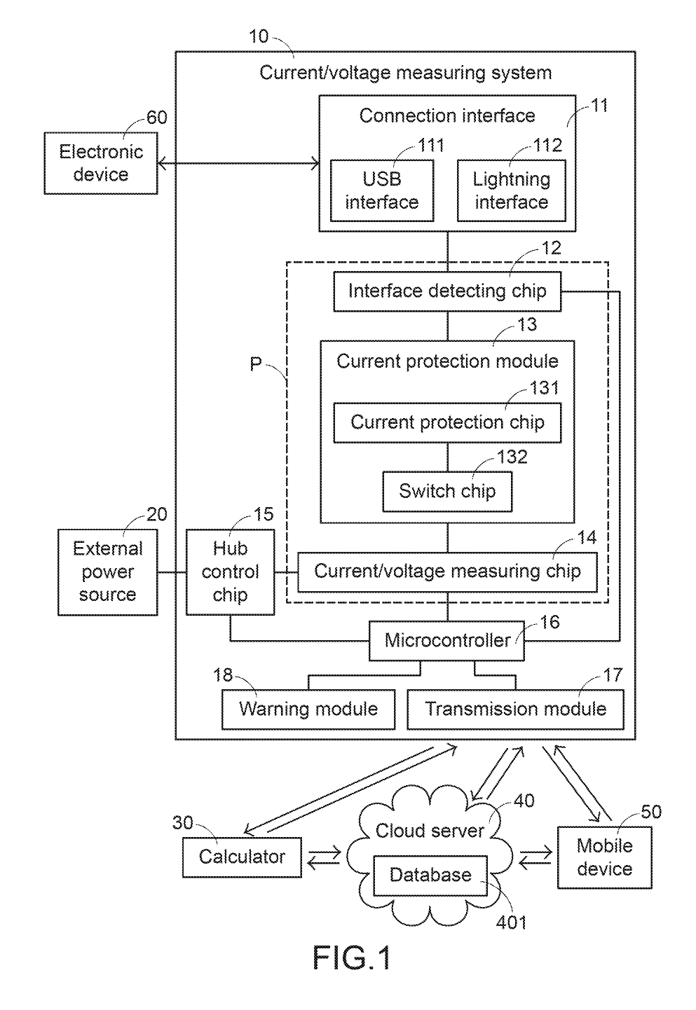

FIG. 1 is a schematic functional block diagram illustrating a current/voltage measuring system according to an embodiment of the present invention. The current/voltage measuring system 10 is applied to a production line to measure a current value and a voltage value of an electronic device 60. As shown in FIG. 1, the current/voltage measuring system 10 comprises a connection interface 11, an interface detecting chip 12, a current protection module 13, a current/voltage measuring chip 14, a hub control chip 15, a microcontroller 16, a transmission module 17 and a warning module 18.

The interface detecting chip 12 is electrically connected with the connection interface 11, the current protection module 13 and the microcontroller 16. The connection interface 11 comprises a USB interface 111 and a lightning interface 112. An example of the USB interface 111 includes but is not limited to a USB 2.0 interface, a USB 3.0 interface or a USB 3.1 interface. The lightning interface 112 has a built-in lightning interface controller (not shown). According to the interface type of the electronic device 60, the electronic device 60 is plugged into the corresponding transmission interface of the connection interface 11. For example, if the transmission interface of the electronic device 60 is a USB 2.0 interface, the electronic device 60 is plugged into the USB 2.0 interface of the USB interface 111. Then, through the interface detecting chip 12, the microcontroller 16 detects the interface type of the electronic device 60 that is connected with the connection interface 11.

The current protection module 13 is electrically connected with the interface detecting chip 12 and the current/voltage measuring chip 14. Moreover, the current/voltage measuring chip 14, the interface detecting chip 12 and the current protection module 13 are electrically connected with each other and collaboratively defined as a power supply circuit P for powering the connection interface 11. When the electronic device 60 is connected with the connection interface 11, the current protection module 13 judges whether the connection interface 11 connected with the electronic device 60 is in an overloading condition.

In an embodiment, the current protection module 13 comprises a current protection chip 131 and a switch chip 132. The current protection chip 131 is used for detecting whether the connection interface 11 is in the overloading condition. When the current protection chip 131 detects that the connection interface 11 is in the overloading condition, the current protection chip 131 turns off the switch chip 132. Since the switch chip 132 is turned off, the power supply circuit P is interrupted and the functions of protecting the current/voltage measuring system 10 and the electronic device 60 are achieved. In the above embodiment, the current protection module 13 comprises one current protection chip 131 and one switch chip 132. It is noted that the numbers of the current protection chip 131 and the switch chip 132 may be varied according to the numbers of the USB interface 111 and the lightning interface 112 of the connection interface 11. In other words, the current protection module 13 is equipped with one or more current protection chips 131 and one or more switch chips 132.

The microcontroller 16 is electrically connected with the interface detecting chip 12, the current/voltage measuring chip 14, the hub control chip 15, the transmission module 17 and a warning module 18.

The hub control chip 15 is electrically connected with an external power source 20. The external power source 20 provides electric energy for powering the current/voltage measuring system 10. Moreover, the hub control chip 15 distributes and provides a rated current to the connection interface 11 through the power supply circuit P.

After the microcontroller 16 detects the interface type of the electronic device 60 through the interface detecting chip 12, the microcontroller 16 controls the hub control chip 15 to output the rated current to the connection interface 11 through the power supply circuit P according to the interface type of the electronic device 60. After the electronic device 60 receives the rated current from the connection interface 11, the electronic device 60 is powered by the rated current.

As mentioned above, the hub control chip 15 to output the rated current according to the interface type of the electronic device 60. Moreover, the relationships between the rated current and the operation voltage range of the interface are listed in Table 1.

TABLE 1

| Interface type | Rated current | Operation voltage range |
|---|---|---|
| USB 2.0 | 500 mA | 4.375 V~5.25 V |
| USB 3.0 | 900 mA | 4.375 V~5.25 V |
| USB 3.1 | 5000 mA | 5 V [symbol] 12 V [symbol] 20 V |
| Lightning interface | 2100 mA | 4.375 V~5.25 V |

During operation of the electronic device 60, the current/voltage measuring chip 14 reads the current value and the voltage value of the electronic device 60 and transmits the current value and the voltage value of the electronic device 60 to the microcontroller 16. Then, the microcontroller 16 judges whether the current value and the voltage value of the electronic device 60 comply with the production specifications of the electronic device 60. Then, the microcontroller 16 generates a test record about the electronic device 60. In the above embodiment, the current/voltage measuring system 10 performs a single measuring operation on the single electronic device 60. In some other embodiments, the current/voltage measuring system 10 performs one or more measuring operations to measure the current value and the voltage value according to the type of the electronic device 60. For example, after ten repeated measuring operations are performed on the electronic device 60, ten sets of current values and voltage values are obtained. After the average current value and the average voltage are obtained, the microcontroller 16 judges whether the average current value and the average voltage value of the electronic device 60 comply with the production specifications of the electronic device 60.

After the test record about the electronic device 60 is generated, the microcontroller 16 transmits the test record to the external control platform through the transmission module 17. For example, the control platform is a calculator 30, a cloud server 40 or a mobile device 50. The mobile device 50 is a notebook computer, a tablet computer, a personal digital assistant (PDA) or a smart phone. The transmission module 17 is a wired transmission module or a wireless transmission module. An example of the wired transmission module includes but is not limited to an Ethernet transmission module, a token-ring transmission module or a fiber-optic communication module. An example of the wireless transmission module includes but is not limited to an infrared transmission module, a Bluetooth transmission module, a ZigBee wireless network module or a Wi-Fi transmission module.

Moreover, the test record of the electronic device 60 may be transmitted between the calculator 30, the cloud server 40 and the mobile device 50 in a wired transmission manner or a wireless transmission manner For example, the test record of the electronic device 60 is transmitted from the microcontroller 16 to the calculator 30 through the transmission module 17. Consequently, the operator on the production line can realize the test record and other information through a display device (not shown) of the calculator 30. In addition, the test record of the electronic device 60 can be uploaded from the calculator 30 to a database 401 of the cloud server 40 in the wired transmission manner or the wireless transmission manner. Moreover, the line administrator with the mobile device 50 can download the test record of the electronic device 60 from the database 401 of the cloud server 40 through the mobile device 50 in the wired transmission manner or the wireless transmission manner. Consequently, the line administrator can realize and monitor the test condition of the electronic device 60 on the production line in real time.

Alternatively, the test record of the electronic device 60 is transmitted from the microcontroller 16 to the cloud server 40 through the transmission module 17, and the test record of the electronic device 60 is stored in the database 401. Then, the test record of the electronic device 60 is downloaded from the database 401 of the cloud server 40 to the calculator 30 in the wired transmission manner or the wireless transmission manner. Consequently, the operator on the production line can realize the test record and other information through a display device (not shown) of the calculator 30. Moreover, the line administrator with the mobile device 50 can download the test record of the electronic device 60 from the database 401 of the cloud server 40 through the mobile device 50 in the wired transmission manner or the wireless transmission manner. Consequently, the line administrator can realize and monitor the test condition of the electronic device 60 on the production line in real time.

Alternatively, the test record of the electronic device 60 is transmitted from the microcontroller 16 to the mobile device 50 through the transmission module 17. Consequently, the line administrator with the mobile device 50 realizes the test condition of the electronic device 60 on the production line through the mobile device 50 in real time. In addition, the test record of the electronic device 60 can be uploaded from the mobile device 50 to the database 401 of the cloud server 40 in the wired transmission manner or the wireless transmission manner. Then, the test record of the electronic device 60 can be downloaded from the database 401 of the cloud server 40 through the calculator 30 in the wired transmission manner or the wireless transmission manner. Consequently, the operator on the production line can realize the test record and other information through the display device of the calculator 30.

Please refer to FIG. 1 again. After the test record is transmitted from the microcontroller 16 to the control platform through the transmission module 17 and the test record is completely transmitted, the microcontroller 16 provides a test completion message to the warning module 18. The test completion message is shown on or emitted by the warning module 18 to notify the operator on the production line that the testing process is completed. Meanwhile, the operator may remove the electronic device 60 from the current/voltage measuring system 10 and allow a next electronic device 60 to be tested by the current/voltage measuring system 10. Moreover, if the connection interface 11 is in the overloading condition when the current/voltage measuring system 10 measures the current value and the voltage value of the electronic device 60, the current protection module 13 interrupts the power supply circuit P instantly. Moreover, the microcontroller 16 writes a message “overloading condition, untested” into the test record of the electronic device 60 and generates a warning message to the warning module 18. The warning message is shown on or emitted by the warning module 18 to notify the operator on the production line that the electronic device 60 needs to be removed to avoid damage of the current/voltage measuring system 10 or the electronic device 60 in the overloading condition. An example of the warning module 18 includes but is not limited to a display screen, a warning light or a sound generation module. In case that the warning module 18 is a display screen, the character symbol of the test completion message or the warning message is directly shown on the display screen. In case that the warning module 18 is a warning light, the green light denotes the test completion message and the red light denotes the warning message. In case that the warning module 18 is a sound generation module, the short buzz denotes the test completion message and the long buzz denotes the warning message.

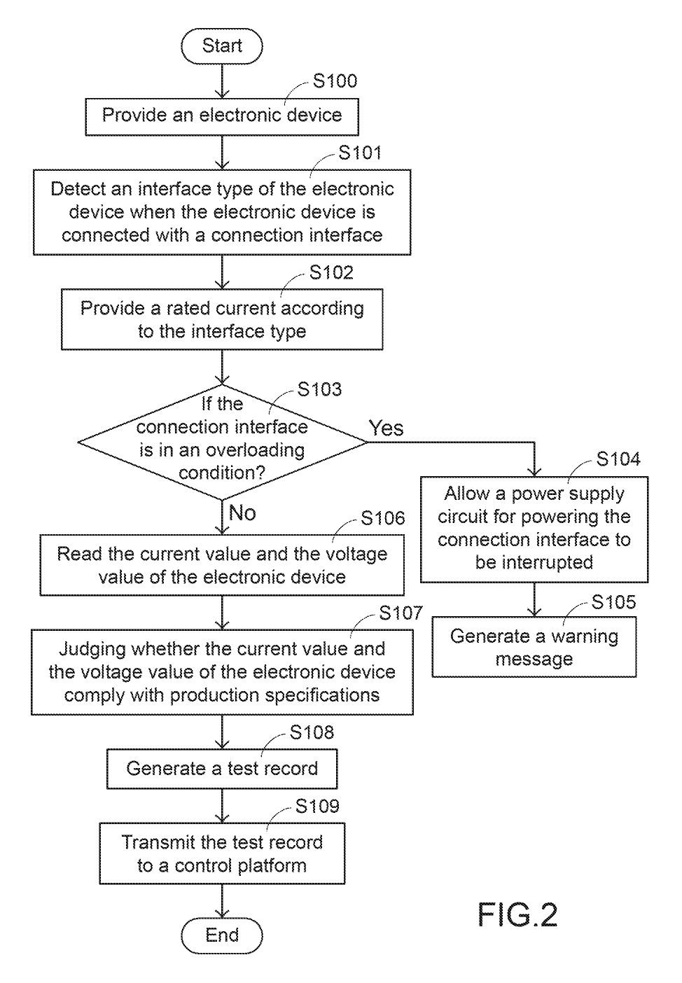

Please refer to FIGS. 1 and 2. FIG. 2 is a flowchart illustrating a current/voltage measuring method according to an embodiment of the present invention. Firstly, an electronic device 60 is provided (Step S100). The electronic device 60 has a USB interface or a lightning interface for transmitting data or transmitting electric power. Then, an interface type of the electronic device 60 connected with the connection interface 11 is detected (Step S101). In the step S101, the electronic device 60 is plugged into the corresponding transmission interface of the connection interface 11 according to the interface type of the electronic device 60, and then the microcontroller 16 detects the interface type of the electronic device 60 through the interface detecting chip 12. After the interface type of the electronic device 60 is realized, a rated current is provided according to the interface type (Step S102). In the step S102, the microcontroller 16 controls the hub control chip 15 to provide a rated current to the connection interface 11 through the power supply circuit P according to the interface type of the electronic device 60. After the electronic device 60 receives the rated current from the connection interface 11, the electronic device 60 is powered by the rated current. Then, the microcontroller 16 judges whether the connection interface 11 is in an overloading condition (Step S103). In the step S103, the current protection chip 131 of the current protection module 13 detects whether the connection interface 11 is in the overloading condition. If the judging condition of the step S103 is satisfied, a power supply circuit P for powering the connection interface 11 is interrupted (Step S104). In the step S104, the current protection chip 131 of the current protection module 13 turns off the switch chip 132. Since the switch chip 132 is turned off, the power supply circuit P is interrupted and the function of protecting the current/voltage measuring system 10 and the electronic device 60 is achieved. Then, a warning message is generated (Step S105). In the step S105, the microcontroller 16 generates a warning message to the warning module 18. The warning message is shown on or emitted by the warning module 18 to notify the operator on the production line to remove the electronic device 16. Consequently, the current/voltage measuring system 10 and the electronic device 60 are not damaged in the overloading condition.

Please refer to FIG. 2 again. If the judging condition of the step S103 is not satisfied, the current value and the voltage value of the electronic device 60 are read (Step S106). In the step S106, the current/voltage measuring chip 14 performs one or more measuring operations to measure the current value and the voltage value of the electronic device 60 during the operation of the electronic device 60. Moreover, the current value and the voltage value of the electronic device 60 are provided to the microcontroller 16. Then, the microcontroller 16 judges whether the current value and the voltage value of the electronic device 60 comply with the production specifications (Step S107). Moreover, in the step S107, the microcontroller 16 judges whether the electronic device 60 complies with the production specifications according to the current value and the voltage value of the electronic device 60 or the average current and the average voltage. Then, the microcontroller 16 generates a test record (Step S108) and transmits the test record to a control platform (Step S109). In the step S109, the test record is transmitted from the microcontroller 16 to the control platform through the transmission module. The control platform is a calculator 30, a cloud server 40 or a mobile device 50. Consequently, the line administrator with the mobile device 50 can realize and monitor the test condition of the electronic device 60 on the production line in real time.

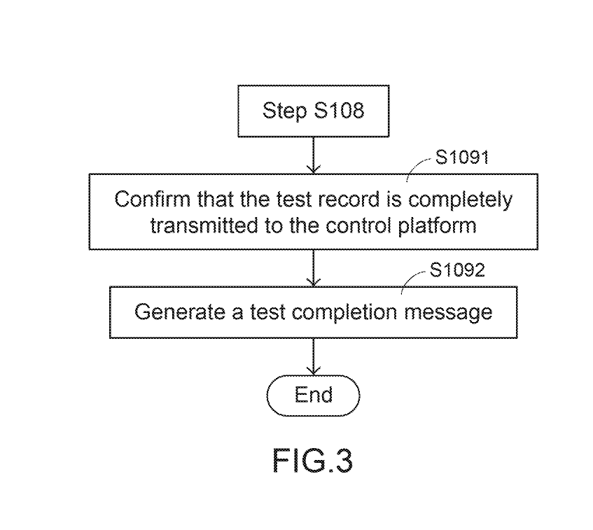

FIG. 3 is a flowchart illustrating the step S109 of the current/voltage measuring method of FIG. 2. As shown in FIG. 3, the step S109 comprises steps S1091 and S1092. In the step S1091, the test record is completely transmitted to the control platform. In the step S1092, a test completion message is generated. The test completion message is shown on or emitted by the warning module 18 to notify the operator on the production line that the testing process is completed. Meanwhile, the operator may remove the electronic device 60 from the current/voltage measuring system 10 and allow a next under-test electronic device 60 to be tested by the current/voltage measuring system 10.

In comparison with the conventional technology, the current/voltage measuring system 10 has many benefits. For example, the current/voltage measuring system 10 is equipped with the current protection module 13 for avoiding the damage of the current/voltage measuring system 10 and the electronic device 60 in the overloading condition. The test record can be transmitted to the calculator 30, the cloud server 40, the mobile device 50 or any external control platform through the transmission module 17 in real time. In addition, the test record is stored, analyzed and displayed by the control platform. Consequently, the operator or the administrator on the production line can realize and monitor the test condition of the electronic device 60 in real time. In other words, the current/voltage measuring system of the present invention is industrially valuable.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all modifications and similar structures.

What is claimed is:

1. A current/voltage measuring system for measuring a current value and a voltage value of an electronic device, the current/voltage measuring system comprising:
a connection interface;
an interface detecting chip electrically connected with the connection interface;
a current protection module electrically connected with the interface detecting chip, wherein the current protection module judges whether the connection interface is in an overloading condition;
a current/voltage measuring chip electrically connected with the current protection module;
a hub control chip electrically connected with the current/voltage measuring chip;
a microcontroller electrically connected with the interface detecting chip, the current/voltage measuring chip and the hub control chip; and
a transmission module electrically connected with the microcontroller,
wherein after the electronic device is connected with the connection interface, the microcontroller detects an interface type of the electronic device through the interface detecting chip, the microcontroller controls the hub control chip to output a rated current to the connection interface according to the interface type, the current/voltage measuring chip reads the current value and the voltage value and transmits the current value and the voltage value to the microcontroller, the microcontroller generates a test record according to the current value and the voltage value, and the microcontroller transmits the test record to a control platform through the transmission module.

2. The current/voltage measuring system according to claim 1, wherein the connection interface comprises a USB interface or a lightning interface.

3. The current/voltage measuring system according to claim 2, wherein the USB interface is a USB 2.0 interface, a USB 3.0 interface or a USB 3.1 interface.

4. The current/voltage measuring system according to claim 1, wherein the current protection module comprises at least one current protection chip and at least one switch chip.

5. The current/voltage measuring system according to claim 1, wherein the at least one current protection chip detects whether the connection interface is in the overloading condition, wherein if the connection interface is in the overloading condition, a power supply circuit is interrupted by the switch chip.

6. The current/voltage measuring system according to claim 1, wherein the hub control chip is electrically connected with an external power source, and the external power source provides electric energy for powering the current/voltage measuring system.

7. The current/voltage measuring system according to claim 1, wherein the transmission module is a wired transmission module or a wireless transmission module.

8. The current/voltage measuring system according to claim 7, wherein the wired transmission module is an Ethernet transmission module, a token-ring transmission module or a fiber-optic communication module.

9. The current/voltage measuring system according to claim 7, wherein the wireless transmission module includes is an infrared transmission module, a Bluetooth transmission module, a ZigBee wireless network module or a Wi-Fi transmission module.

10. The current/voltage measuring system according to claim 1, wherein the control platform is a calculator, a cloud server or a mobile device.

11. The current/voltage measuring system according to claim 10, wherein the mobile device is a notebook computer, a tablet computer, a personal digital assistant or a smart phone.

12. The current/voltage measuring system according to claim 1, further comprising a warning module, wherein a warning message or a test completion message is shown on or emitted by the warning module.

13. A current/voltage measuring method for measuring a current value and a voltage value of an electronic device, the current/voltage measuring method comprising steps of:
(a) providing the electronic device;
(b) detecting an interface type of the electronic device when the electronic device is connected with a connection interface;
(c) providing a rated current according to the interface type;
(d) judging whether the connection interface is in an overloading condition, wherein if the connection interface is in the overloading condition, a power supply circuit for powering the connection interface is interrupted, wherein if the connection interface is not in the overloading condition, a next step is performed;
(e) reading the current value and the voltage value of the electronic device;
(f) judging whether the current value and the voltage value of the electronic device comply with production specifications;
(g) generating a test record; and
(h) transmitting the test record to a control platform.

14. The current/voltage measuring method according to claim 13, wherein the step (h) further comprises a step of generating a test completion message to the control platform after the test record is completely transmitted to the control platform.
